(19) United States
(12) Patent Application Publication
(10) Pub. No.: US 2025/0393166 A1
(43) Pub. Date: Dec. 25, 2025

(54) METHOD AND APPARATUS FOR CONTROLLING TWO-PHASE COLD PLATE LIQUID COOLING SYSTEM, AND SYSTEM

(71) Applicant: SUZHOU METABRAIN INTELLIGENT TECHNOLOGY CO.,LTD., Jiangsu (CN)

(72) Inventor: Huanlai ZHU, Jiangsu (CN)

(73) Assignee: SUZHOU METABRAIN INTELLIGENT TECHNOLOGY CO.,LTD., Jiangsu (CN)

(21) Appl. No.: 18/879,010

(22) PCT Filed: Dec. 18, 2023
(86) PCT No.: PCT/CN2023/139590

§ 371 Date: Dec. 26, 2024

(30) Foreign Application Priority Data
Mar. 8, 2023 (CN) 202310218228.7

(51) Int. Cl. H05K 7/20

(52) U.S. Cl. CPC H05K 7/20345; H05K 7/20309; H05K 7/20318; H05K 7/20327

(57) ABSTRACT

Embodiments of this application provide a method and apparatus for controlling a two-phase cold plate liquid cooling system, and a system. The method includes: controlling a gas extraction tube to extract a gaseous medium from an outlet of an evaporator in an operation process of the two-phase cold plate liquid cooling system, where the two-phase cold plate liquid cooling system at least includes the gas extraction tube and the evaporator; condensing the gaseous medium in a condenser of the two-phase cold plate liquid cooling system to obtain a first liquid-phase medium corresponding to the gaseous medium; and controlling a nozzle of the two-phase cold plate liquid cooling system to spray the first liquid-phase medium into the outlet of the evaporator, where the first liquid-phase medium is used to absorb gaseous latent heat of the gaseous medium at the outlet of the evaporator. This application solves the technical problem of poor stability of the two-phase cold plate liquid cooling system.

### CROSS-REFERENCE TO RELATED APPLICATION

This application is a National Stage Application of International Application No. PCT/CN2023/139590 filed on Dec. 18, 2023, which claims the benefit of Serial No. 202310218228.7 filed on Mar. 8, 2023 in China, and which applications are incorporated herein by reference. To the extent appropriate, a claim of priority is made to each of the above disclosed applications.

### TECHNICAL FIELD

Embodiments of this application relate to the technical field of computer cooling, and in particular, to a method and apparatus for controlling a two-phase cold plate liquid cooling system, and a system.

### BACKGROUND

Currently, a two-phase cold plate often reuses a single-phase multi-channel equal-height flat parallel flow channel structure, but due to essential differences in internal flow characteristics between the two-phase cold plate and a single-phase cold plate, in a flowing direction of a working medium, a gas phase continuously increases while a liquid phase continuously decreases, accompanied by a continuous increase in dryness fraction, which may easily cause the phenomenon of a sharp increase in volumetric flow rate, resulting in the technical problem of poor stability of a two-phase cold plate liquid cooling system.

An effective solution has not yet been proposed to solve the technical problem of poor stability of the above two-phase cold plate liquid cooling system.

### SUMMARY

Embodiments of this application provide a method and apparatus for controlling a two-phase cold plate liquid cooling system, and a system, so as to at least solve the technical problem of poor stability of a two-phase cold plate liquid cooling system in the related art.

According to one aspect of the embodiments of this application, a method for controlling a two-phase cold plate liquid cooling system is provided. The method may include: controlling a gas extraction tube to extract a gaseous medium from an outlet of an evaporator in an operation process of the two-phase cold plate liquid cooling system, where the two-phase cold plate liquid cooling system at least includes the gas extraction tube and the evaporator; condensing the gaseous medium in a condenser of the two-phase cold plate liquid cooling system to obtain a first liquid-phase medium corresponding to the gaseous medium; and controlling a nozzle of the two-phase cold plate liquid cooling system to spray the first liquid-phase medium into the outlet of the evaporator, where the first liquid-phase medium is used to absorb gaseous latent heat of the gaseous medium at the outlet of the evaporator.

Optionally, before condensing the gaseous medium, the method may further include: conveying the gaseous medium into a heat exchanger of the two-phase cold plate liquid cooling system, where the heat exchanger is configured to heat the gaseous medium.

Optionally, the method may further include: controlling a spray circulating pump of the two-phase cold plate liquid cooling system to drive the first liquid-phase medium to be sprayed into the outlet of the evaporator.

Optionally, the nozzle of the two-phase cold plate liquid cooling system is controlled to spray the first liquid-phase medium into the outlet of the evaporator, and the method may include: controlling the spray circulating pump to drive the nozzle at the outlet of the evaporator to spray the first liquid-phase medium into the outlet of the evaporator.

Optionally, the method may include: conveying the first liquid-phase medium into the heat exchanger to obtain a second liquid-phase medium, where the second liquid-phase medium is in a saturated liquid state, and the heat exchanger is configured to heat the first liquid-phase medium; converting the second liquid-phase medium from the saturated liquid state to a gas-liquid two-phase flow state to obtain a gas-liquid two-phase flow medium; and conveying the gas-liquid two-phase flow medium into the condenser, where the gas-liquid two-phase flow medium is used for condensation treatment by the condenser.

Optionally, the second liquid-phase medium is converted from the saturated liquid state to the gas-liquid two-phase flow state to obtain the gas-liquid two-phase flow medium. The method may further include: conveying the second liquid-phase medium into a first evaporator to obtain an original gas-liquid two-phase flow medium, where the first evaporator is configured to absorb heat from the second liquid-phase medium; and conveying the original gas-liquid two-phase flow medium into a second evaporator from the first evaporator to obtain the gas-liquid two-phase flow medium, where the second evaporator is configured to absorb heat from the original gas-liquid two-phase flow medium, and a dryness fraction of the gas-liquid two-phase flow medium is greater than that of the original gas-liquid two-phase flow medium.

Optionally, the first liquid-phase medium is conveyed into the heat exchanger, and the method may include: driving, based on a main circulating pump, the first liquid-phase medium to be conveyed into the heat exchanger.

Optionally, the first liquid-phase medium is subcooled liquid coolant.

According to one aspect of the embodiments of this application, a two-phase cold plate liquid cooling system is provided. The system may include: a gas extraction tube, configured to extract a gaseous medium from an outlet of an evaporator; a condenser, configured to condense the gaseous medium to obtain a first liquid-phase medium corresponding to the gaseous medium; and a nozzle, configured to spray the first liquid-phase medium into the outlet of the evaporator.

Optionally, the two-phase cold plate liquid cooling system further includes: a heat exchanger, where the heat exchanger is configured to heat the gaseous medium before condensing the gaseous medium.

Optionally, the heat exchanger is further configured to heat the first liquid-phase medium to obtain a second liquid-phase medium, where the second liquid-phase medium is in a saturated liquid state.

Optionally, the two-phase cold plate liquid cooling system further includes: a first evaporator and a second evaporator. The first evaporator is configured to absorb heat from the second liquid-phase medium to obtain an original gas-liquid two-phase flow medium. The second evaporator is configured to absorb heat from the original gas-liquid two-phase flow medium. A dryness fraction of a gas-liquid two-phase flow medium is greater than that of the original gas-liquid two-phase flow medium.

Optionally, the condenser is further configured to condense the gas-liquid two-phase flow medium.

Optionally, the two-phase cold plate liquid cooling system further includes: the main circulating pump, where the main circulating pump is configured to drive the first liquid-phase medium to be conveyed into the heat exchanger, wherein the heat exchanger is configured to heat the gaseous medium before condensing the gaseous medium.

Optionally, the nozzle and the gas extraction tube are located at the outlet of the evaporator.

According to another aspect of the embodiments of this application, a non-volatile readable storage medium is further provided, and includes a stored program. The computer program, when being executed on a processor, causes the processor to execute operations comprising: controlling a gas extraction tube to extract a gaseous medium from an outlet of an evaporator in an operation process of the two-phase cold plate liquid cooling system, wherein the two-phase cold plate liquid cooling system at least comprises the gas extraction tube and the evaporator; condensing the gaseous medium in a condenser of the two-phase cold plate liquid cooling system to obtain a first liquid-phase medium corresponding to the gaseous medium; and controlling a nozzle of the two-phase cold plate liquid cooling system to spray the first liquid-phase medium into the outlet of the evaporator, wherein the first liquid-phase medium is used to absorb gaseous latent heat of the gaseous medium at the outlet of the evaporator.

Optionally, the two-phase cold plate liquid cooling system comprises a spray circulating pump, wherein the spray circulating pump is configured to drive the first liquid-phase medium to be sprayed into the outlet of the evaporator.

Optionally, the first liquid-phase medium is subcooled liquid coolant.

According to the embodiments of this application, in the operation process of the two-phase cold plate liquid cooling system, the gas extraction tube is controlled to extract the gaseous medium from the outlet of the evaporator, where the two-phase cold plate liquid cooling system at least includes the gas extraction tube and the evaporator; in the condenser of the two-phase cold plate liquid cooling system, the gaseous medium is condensed to obtain the first liquid-phase medium corresponding to the gaseous medium; and the nozzle of the two-phase cold plate liquid cooling system is controlled to spray the first liquid-phase medium into the outlet of the evaporator, where the first liquid-phase medium is used to absorb the gaseous latent heat of the gaseous medium at the outlet of the evaporator. In other words, in the operation process of the two-phase cold plate liquid cooling system according to the embodiments of this application, a gas extraction line is added to the outlet of each evaporator, so as to extract part of the gaseous medium in time, thereby reducing a gaseous volume, avoiding the phenomenon of sudden increases in flow velocity and pressure, then, solving the technical problem of poor stability of the two-phase cold plate liquid cooling system, and achieving the technical effect of improving stability of the two-phase cold plate liquid cooling system.

### BRIEF DESCRIPTION OF THE DRAWINGS

FIG. 1 is a flowchart of a method for controlling a two-phase cold plate liquid cooling system according to an embodiment of this application;

FIG. 2 is a schematic diagram of a two-phase cold plate liquid cooling system according to an embodiment of this application;

FIG. 3 is a schematic diagram of another two-phase cold plate liquid cooling system according to an embodiment of this application;

FIG. 4 is a schematic diagram of an implementation solution of a method for controlling a two-phase cold plate liquid cooling system according to an embodiment of this application; and

FIG. 5 is a flowchart of an apparatus for controlling a two-phase cold plate liquid cooling system.

### DETAILED DESCRIPTION OF THE EMBODIMENTS

In order to make those skilled in the art better understand solutions of this application, the technical solutions in the embodiments of this application are clearly and completely described in conjunction with the accompanying drawings in the embodiments of this application as below, and it is apparent that the described embodiments are merely a part rather all the embodiments of this application. Based on the embodiments of this application, all other embodiments obtained by those of ordinary skill in the art without creative labor shall fall within the scope of protection of this application.

It should be noted that the terms such as “first” and “second” of the specification and claims of this application and the foregoing accompanying drawings are used to distinguish similar objects but are not necessarily intended to describe optional sequences or precedence orders. It should be understood that such used data is interchangeable where appropriate, such that the embodiments of this application described herein may be implemented in an order other than those illustrated or described herein. In addition, the terms “include”, “have”, and any variations thereof are intended to encompass non-exclusive inclusions. For example, a process, a method, a system, a product, or a device including a series of steps or units is not necessarily limited to those explicitly-listed steps or units, but may include other steps or units that are not explicitly listed or inherent to the process, the method, the system, the product, or the device.

According to an embodiment of this application, a method for controlling a two-phase cold plate liquid cooling system is provided. It should be noted that the steps shown in the flowcharts of the accompanying drawings may be performed in a computer system such as a set of computer executable instructions. In addition, although a logical sequence is shown in the flowcharts, the illustrated or described steps may be performed in a different sequence than presented herein in some cases.

The method for controlling a two-phase cold plate liquid cooling system according to this embodiment of this application is introduced below.

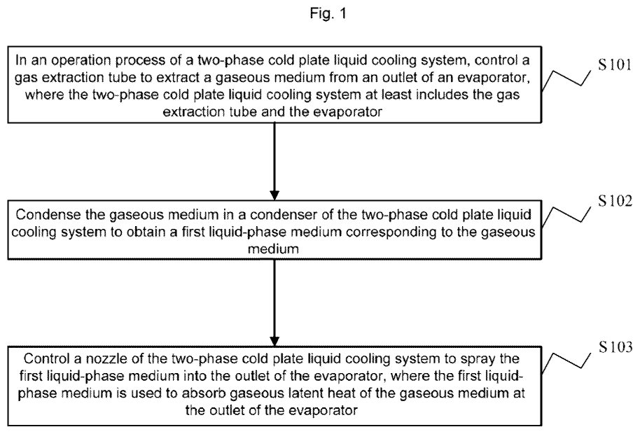

FIG. 1 is a flowchart of a method for controlling a two-phase cold plate liquid cooling system according to an embodiment of this application. As shown in FIG. 1, the method may include the following steps:

Step S101: In an operation process of the two-phase cold plate liquid cooling system, control a gas extraction tube to extract a gaseous medium from an outlet of an evaporator, where the two-phase cold plate liquid cooling system at least includes the gas extraction tube and the evaporator.

According to the technical solution provided in the above step S101 in this application, in the operation process of the two-phase cold plate liquid cooling system, the gas extraction tube may be controlled to extract the gaseous medium from the outlet of the evaporator to provide gaseous phase power. The evaporator may be configured to exchange heat between low-temperature liquid and outside air. After absorbing heat, the liquid may be converted into liquid with a certain dryness fraction.

In this embodiment, the two-phase cold plate liquid cooling system may control the gas extraction tube to extract part of the gaseous medium from the outlet of the evaporator, to achieve the purposes of reducing a gaseous volume, lowering a local pressure, and inhibiting gas blockages.

For example, assuming that the evaporator produces 10 kg of gaseous medium, the two-phase cold plate liquid cooling system may extract 5 kg of gaseous medium, and backflow spray cooling liquid then condenses 1 kg of gaseous medium. The evaporator only circulates 4 kg of gaseous medium through a main circulation loop, which is equivalent to 40% of the original amount, thereby significantly reducing the gaseous volume (I.e., flow velocity), lowering the local pressure, and inhibiting the gas blockages.

Step S102: Condense the gaseous medium in a condenser of the two-phase cold plate liquid cooling system to obtain a first liquid-phase medium corresponding to the gaseous medium.

According to the technical solution provided in the above step S102 in this application, the condenser of the two-phase cold plate liquid cooling system may be configured to condense the gaseous medium, so as to obtain the first liquid-phase medium corresponding to the gaseous medium, where the first liquid-phase medium may be subcooled liquid.

Optionally, through the condenser of the two-phase cold plate liquid cooling system, the subcooled liquid after condensation treatment may be obtained, and the subcooled liquid flows through other apparatuses to start a cooling cycle process, where the other apparatuses may be a main circulating pump, the heat exchanger, etc., which are not limited herein.

For example, assuming quantitative data for a R134A refrigerant with a latent heat of vaporization of approximately 160 kj/kg and an optional heat capacity of a liquid state of approximately 1.6 kj/(kg ° C.), when a subcooling degree of subcooled liquid saturated liquid is 20° C. according to a formula Q=CMΔT, M=Q/(CΔT)=160/(1.6*20)=5, meaning that 5 kg of subcooled spray liquid may condense 1 kg of gaseous medium.

Step S103: Control a nozzle of the two-phase cold plate liquid cooling system to spray the first liquid-phase medium into the outlet of the evaporator.

According to the technical solution provided in the above step S103 in this application, the nozzle may be configured to spray the first liquid-phase medium into the outlet of the evaporator, where the first liquid-phase medium is used to absorb gaseous latent heat of the gaseous medium at the outlet of the evaporator.

In this embodiment, the two-phase cold plate liquid cooling system may control the nozzle to spray the first liquid-phase medium into the outlet of the evaporator, thereby allowing subcooled cooling liquid to absorb part of the gaseous latent heat, causing part of the gaseous medium to condense into a saturated liquid state, and reducing the gaseous volume. Meanwhile, a spray effect may be used to disperse disturbances and eliminate annular and slug flow bubbles to the greatest extent, so as to inhibit the gas blockages.

According to the above steps S101 to S103 in this application, in the operation process of the two-phase cold plate liquid cooling system, the gas extraction tube is controlled to extract the gaseous medium from the outlet of the evaporator, where the two-phase cold plate liquid cooling system at least includes the gas extraction tube and the evaporator; in the condenser of the two-phase cold plate liquid cooling system, the gaseous medium is condensed to obtain the first liquid-phase medium corresponding to the gaseous medium; and the nozzle of the two-phase cold plate liquid cooling system is controlled to spray the first liquid-phase medium into the outlet of the evaporator, where the first liquid-phase medium is used to absorb the gaseous latent heat of the gaseous medium at the outlet of the evaporator. In other words, in the operation process of the two-phase cold plate liquid cooling system according to this embodiment of this application, the gas extraction tube may be controlled to extract the gaseous medium from the outlet of the evaporator, the condenser is used to condense the gaseous medium to obtain the first liquid-phase medium corresponding to the gaseous medium, and the first liquid-phase medium may be sprayed into the outlet of the evaporator through the nozzle of the two-phase cold plate liquid cooling system, such that the subcooled cooling liquid absorbs part of the gaseous latent heat, thereby reducing the gaseous volume and inhibiting the gas blockages, so as to solve the technical problem of poor stability of the two-phase cold plate liquid cooling system, and achieve the technical effect of improving stability of the two-phase cold plate liquid cooling system.

The above method of this embodiment is further described below.

As an optional embodiment, before condensing the gaseous medium, the method may further include: conveying the gaseous medium into the heat exchanger of the two-phase cold plate liquid cooling system.

In this embodiment, before condensing the gaseous medium, the heat exchanger of the two-phase cold plate liquid cooling system may be used to heat the gaseous medium, thereby achieving the purpose of eliminating the subcooling degree of the liquid.

As an optional embodiment, a spray circulating pump of the two-phase cold plate liquid cooling system is controlled to drive the first liquid-phase medium to be sprayed into the outlet of the evaporator.

In this embodiment, the spray circulating pump of the two-phase cold plate liquid cooling system may spray the first liquid-phase medium into the outlet of the evaporator, where the spray circulating pump may be configured to provide the liquid phase power.

As an optional embodiment, the step of controlling the nozzle of the two-phase cold plate liquid cooling system to spray the first liquid-phase medium into the outlet of the evaporator includes: controlling the spray circulating pump to drive the nozzle at the outlet of the evaporator to spray the first liquid-phase medium into the outlet of the evaporator.

In this embodiment, the spray circulating pump of the two-phase cold plate liquid cooling system may control the nozzle at the outlet of the evaporator to spray the first liquid-phase medium into the outlet of the evaporator, such that the first liquid-phase medium absorbs heat at the outlet of the evaporator, and is converted into liquid with a high dryness fraction.

As an optional embodiment, the first liquid-phase medium is conveyed into the heat exchanger to obtain a second liquid-phase medium, where the second liquid-phase medium is in a saturated liquid state, and the heat exchanger is configured to heat the first liquid-phase medium. The second liquid-phase medium is converted from the saturated liquid state to a gas-liquid two-phase flow state to obtain the gas-liquid two-phase flow medium. The gas-liquid two-phase flow medium is conveyed into the condenser, where the gas-liquid two-phase flow medium is condensed through the condenser.

In this embodiment, the two-phase cold plate liquid cooling system may convey the first liquid-phase medium into the heat exchanger to obtain the second liquid-phase medium, perform state conversion on the second liquid-phase medium to obtain the gas-liquid two-phase flow medium, and convey the gas-liquid two-phase flow medium into the condenser for condensation treatment, thereby finishing a main cycle. The second liquid-phase medium is in the saturated liquid state, the heat exchanger is configured to heat the first liquid-phase medium, and the gas-liquid two-phase flow medium is condensed through the condenser.

As an optional embodiment, the step of converting the second liquid-phase medium from the saturated liquid state to the gas-liquid two-phase flow state to obtain the gas-liquid two-phase flow medium includes: conveying the second liquid-phase medium into a first evaporator to obtain an original gas-liquid two-phase flow medium; and conveying the original gas-liquid two-phase flow medium from the first evaporator into a second evaporator to obtain the gas-liquid two-phase flow medium.

In this embodiment, in the process of converting the second liquid-phase medium from the saturated liquid state to the gas-liquid two-phase flow state, the second liquid-phase medium is conveyed into the first evaporator so as to obtain the original gas-liquid two-phase flow medium. The original gas-liquid two-phase flow medium is conveyed into the second evaporator to obtain the gas-liquid two-phase flow medium. The first evaporator is configured to perform heat absorption treatment on the second liquid-phase medium, the second evaporator is configured to perform heat absorption treatment on the original gas-liquid two-phase flow medium, and a dryness fraction of the gas-liquid two-phase flow medium is greater than that of the original gas-liquid two-phase flow medium.

As an optional embodiment, the step of conveying the first liquid-phase medium into the heat exchanger includes: driving, based on the main circulating pump, the first liquid-phase medium to be conveyed into the heat exchanger, wherein the heat exchanger is configured to heat the gaseous medium before condensing the gaseous medium.

In this embodiment, the main circulating pump is used to convey the first liquid-phase medium into the heat exchanger, where the main circulating pump may be configured to circulate the liquid condensed through the condenser in a loop of the main circulating pump.

As an optional embodiment, the first liquid-phase medium is subcooled liquid coolant.

In this embodiment, to avoid cavitation in the circulating pump, the first liquid-phase medium is the subcooled liquid coolant.

According to this embodiment of this application, in the operation process of the two-phase cold plate liquid cooling system, the gas extraction tube is controlled to extract the gaseous medium from the outlet of the evaporator, where the two-phase cold plate liquid cooling system at least includes the gas extraction tube and the evaporator; in the condenser of the two-phase cold plate liquid cooling system, the gaseous medium is condensed to obtain the first liquid-phase medium corresponding to the gaseous medium; and the nozzle of the two-phase cold plate liquid cooling system is controlled to spray the first liquid-phase medium into the outlet of the evaporator, where the first liquid-phase medium is used to absorb the gaseous latent heat of the gaseous medium at the outlet of the evaporator. In other words, in the operation process of the two-phase cold plate liquid cooling system according to this embodiment of this application, a gas extraction line is added to the outlet of each evaporator, so as to extract part of the gaseous medium in time, thereby reducing the gaseous volume, avoiding the phenomenon of sudden increases in flow velocity and pressure, then, solving the technical problem of poor stability of the two-phase cold plate liquid cooling system, and achieving the technical effect of improving stability of the two-phase cold plate liquid cooling system.

A two-phase cold plate liquid cooling system that applies the above method for controlling a two-phase cold plate liquid cooling system according to this embodiment of this application is introduced below.

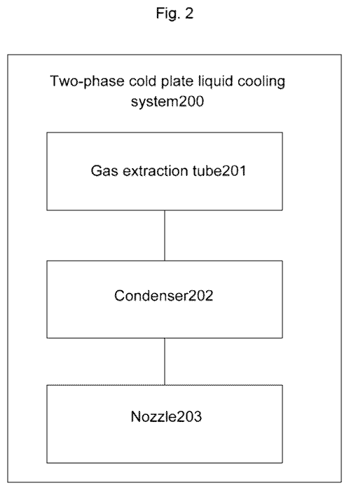

FIG. 2 is a schematic diagram of a two-phase cold plate liquid cooling system according to an embodiment of this application. As shown in FIG. 2, the system may include: a gas extraction tube 201, a condenser 202, and the nozzle 203.

The gas extraction tube 201 is configured to extract a gaseous medium from an outlet of an evaporator.

The condenser 202 is configured to condense the gaseous medium to obtain a first liquid-phase medium corresponding to the gaseous medium.

The nozzle 203 is configured to spray the first liquid-phase medium into the outlet of the evaporator.

In this embodiment, the two-phase cold plate liquid cooling system includes the gas extraction tube, the condenser, and the nozzle. The gas extraction tube is configured to extract the gaseous medium from the outlet of the evaporator, so as to reduce a gaseous volume and a local pressure at the outlet of the evaporator. After the condenser condenses the gaseous medium, the first liquid-phase medium is obtained. The nozzle may spray the first liquid-phase medium into the outlet of the evaporator, and after heat absorption, the first liquid-phase medium is converted into liquid with a high dryness fraction, thereby solving the technical problem of poor stability of the two-phase cold plate liquid cooling system, and achieving the technical effect of improving stability of the two-phase cold plate liquid cooling system.

A two-phase cold plate liquid cooling system applied to the above method for controlling a two-phase cold plate liquid cooling system is introduced below.

Optionally, the two-phase cold plate liquid cooling system includes: the heat exchanger.

In this embodiment, the two-phase cold plate liquid cooling system includes the heat exchanger. The heat exchanger may be configured to transfer heat from a hot fluid to a cold fluid, which may be used to heat the gaseous medium before condensing the gaseous medium.

Optionally, the heat exchanger is further configured to heat the first liquid-phase medium to obtain a second liquid-phase medium.

In this embodiment, the heat exchanger may heat the first liquid-phase medium to obtain the second liquid-phase medium, where the second liquid-phase medium is in a saturated liquid state.

Optionally, the two-phase cold plate liquid cooling system includes: a first evaporator and a second evaporator.

In this embodiment, the two-phase cold plate liquid cooling system includes the first evaporator and the second evaporator. The first evaporator is configured to absorb heat from the second liquid-phase medium to obtain an original gas-liquid two-phase flow medium. The second evaporator is configured to absorb heat from the original gas-liquid two-phase flow medium. A dryness fraction of the gas-liquid two-phase flow medium is greater than that of the original gas-liquid two-phase flow medium.

Optionally, the condenser is further configured to condense the gas-liquid two-phase flow medium.

In this embodiment, the condenser may condense the gas-liquid two-phase flow medium to obtain the first liquid-phase medium.

Optionally, the two-phase cold plate liquid cooling system includes: a main circulating pump.

In this embodiment, the two-phase cold plate liquid cooling system may include the main circulating pump, where the main circulating pump is configured to drive the first liquid-phase medium to be conveyed into the heat exchanger.

Optionally, the nozzle and the gas extraction tube are located at the outlet of the evaporator.

In this embodiment, the nozzle and the gas extraction tube may be located at the outlet of the evaporator, where the nozzle is configured to spray the first liquid-phase medium into the outlet of the evaporator, and the gas extraction tube is configured to extract the gaseous medium from the outlet of the evaporator.

In this embodiment, the two-phase cold plate liquid cooling system includes the gas extraction tube, the condenser, and the nozzle. The gas extraction tube is configured to extract the gaseous medium from the outlet of the evaporator, the condenser is configured to condense the gaseous medium to obtain the first liquid-phase medium corresponding to the gaseous medium, and the nozzle is configured to spray the first liquid-phase medium into the outlet of the evaporator, thereby solving the technical problem of poor stability of the two-phase cold plate liquid cooling system, and achieving the technical effect of improving stability of the two-phase cold plate liquid cooling system.

The technical solutions of the embodiments of this application are exemplified in conjunction with optional implementations as below.

A two-phase cold plate often reuses a single-phase multi-channel equal-height flat parallel flow channel structure, but there are essential differences in internal flow characteristics between the two-phase cold plate and a single-phase cold plate, which are mainly reflected in dynamic changes of gas-liquid two-phase flow states and dryness fraction inside. In a flowing direction of a working medium, a gas phase continuously increases while a liquid phase continuously decreases, accompanied by a continuous increase in dryness fraction. Since the density of the gas phase is two orders of magnitude lower than that of the liquid phase, namely, an optional volume will be two orders of magnitude higher, the phenomenon of a sharp increase in volumetric flow rate occurs. The common multi-channel equal-height flat parallel flow channel structure will inevitably result in phenomena of a sharp increase in flow velocity and pressure due to an unchanged flow channel cross-sectional area. An excessive pressure at a tail end of a two-phase microchannel cold plate flow may cause gas phase stagnation and backflow, leading to the formation of gas blockages. As a result, pressure oscillations of a two-phase flow system are induced, resulting in deteriorated heat transfer and uncontrolled system pressure. Consequently, the local pressure in the two-phase cold plate flow is high, leading to the technical problem of the gas blockages.

Therefore, to solve the above problems, the method for controlling a two-phase cold plate liquid cooling system is provided. By extracting part of the gas phase, the gaseous volume, namely the flow velocity is reduced, and the local pressure is reduced to inhibit the gas blockages. The nozzle is additionally arranged the outlet of the evaporator to absorb part of the gaseous latent heat using the subcooling degree of the subcooled coolant, such that part of the gas phase is re-condensed into the saturated liquid state, thereby further reducing the gaseous volume and reducing the local pressure to inhibit the gas blockages, and meanwhile using the spray effect to disperse disturbances and eliminate annular and slug flow bubbles to the greatest extent, so as to further inhibit the gas blockages.

In this embodiment, in the operation process of the two-phase cold plate liquid cooling system, the gas extraction tube is controlled to extract the gaseous medium from the outlet of the evaporator, where the two-phase cold plate liquid cooling system at least includes the gas extraction tube and the evaporator; in the condenser of the two-phase cold plate liquid cooling system, the gaseous medium is condensed to obtain the first liquid-phase medium corresponding to the gaseous medium; and the nozzle of the two-phase cold plate liquid cooling system is controlled to spray the first liquid-phase medium into the outlet of the evaporator, where the first liquid-phase medium is used to absorb the gaseous latent heat of the gaseous medium at the outlet of the evaporator. This application solves the technical problem of poor stability of the two-phase cold plate liquid cooling system.

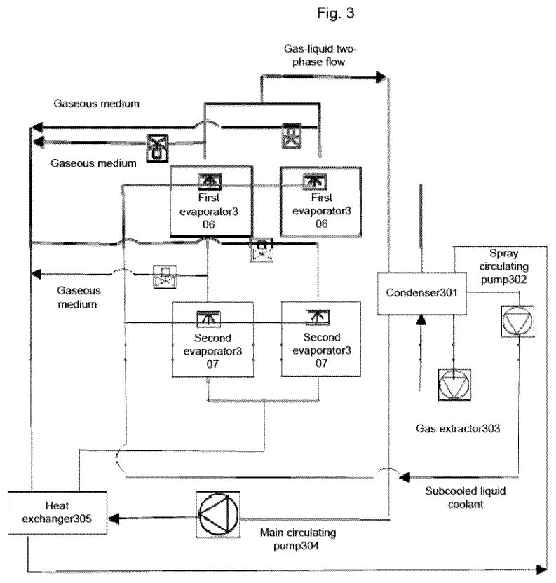

FIG. 3 is a schematic diagram of another two-phase cold plate liquid cooling system according to an embodiment of this application. As shown in FIG. 3, the two-phase cold plate liquid cooling system may include: a condenser 301, a spray circulating pump 302, a gas extractor 303, a main circulating pump 304, the heat exchanger 305, first evaporators 306, and second evaporators 307.

The condenser 301 is configured to convert gas or steam into subcooled liquid coolant and quickly transfer heat inside a tube to air near the tube.

The spray circulating pump 302 is configured to extract steam containing water, as well as flammable and explosive gases containing a small amount of dust and liquid. The spray circulating pump may provide liquid phase power.

The gas extractor 303 is configured to constantly extract non-condensable gases from the condenser to maintain good vacuum conditions and heat transfer conditions in the condenser. The gas extractor may provide gas phase power.

The main circulating pump 304 circulates the subcooled liquid coolant discharged from the condenser in a loop of the main circulating pump and conveys the subcooled liquid coolant to the heat exchanger.

The heat exchanger 305 is an apparatus used to transfer heat from a hot fluid to a cold fluid to meet specified process requirements, and herein, may be used to heat the subcooled liquid coolant.

In each first evaporator 306, low-temperature condensed liquid may pass through the first evaporator to exchange heat with outside air, vaporize, and absorb heat, thereby achieving a refrigeration effect. For example, the heated subcooled liquid coolant is converted into gas-liquid two-phase flow with a certain dryness fraction, and a dual-power auxiliary cycle is added, that is, a gas extraction line is added to an outlet of the first evaporator to extract part of a high-pressure gaseous medium.

Each second evaporator 307 is configured to convert the gas-liquid two-phase flow flowing out of the corresponding first evaporator 306 into gas-liquid two-phase flow with a higher dryness fraction, a gas extraction line is added to an outlet of the second evaporator, and finally, the two-phase flow with the higher dryness fraction enters the condenser to be condensed into subcooled liquid, thereby finishing a main cycle.

In this embodiment, the condenser is configured to convert the gas or the steam into the subcooled liquid coolant and quickly transfer the heat inside the tube to the air near the tube; the spray circulating pump is configured to extract the steam containing water, as well as the flammable and explosive gases containing a small amount of dust and liquid, and may provide the liquid phase power; the gas extractor is configured to constantly extract the non-condensable gases from the condenser to maintain good vacuum conditions and heat transfer conditions in the condenser, and may provide the gas phase power; the main circulating pump circulates the subcooled liquid coolant discharged from the condenser in the loop of the main circulating pump and conveys the subcooled liquid coolant to the heat exchanger; the heat exchanger is the apparatus used to transfer the heat from the hot fluid to the cold fluid to meet the specified process requirements, and herein, may be configured to heat the subcooled liquid coolant; and in each evaporator, the low-temperature condensed liquid may pass through the evaporator to exchange heat with outside air, vaporize, and absorb heat, thereby achieving the refrigeration effect. For example, the heated subcooled liquid coolant is converted into the gas-liquid two-phase flow with a certain dryness fraction, and the dual-power auxiliary cycle is added, that is, the gas extraction line is added to the outlets of the two evaporators to extract part of the high-pressure gaseous medium; and the above gas-liquid two-phase flow is converted into the gas-liquid two-phase flow with the higher dryness fraction, the gas extraction line is added to the outlets of the two evaporators, and finally, the two-phase flow with the higher dryness fraction enters the condenser to be condensed into the subcooled liquid, thereby finishing the main cycle. Therefore, the technical problem of poor stability of the two-phase cold plate liquid cooling system is solved, and the technical effect of improving stability of the two-phase cold plate liquid cooling system is achieved.

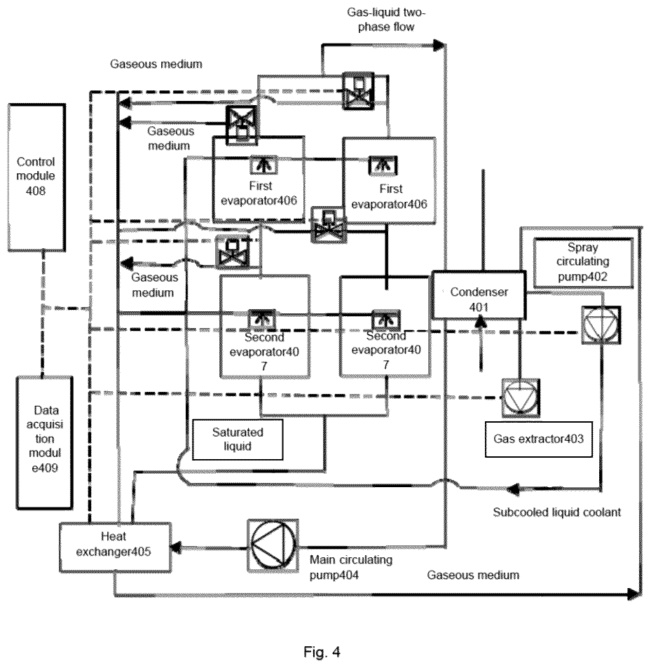

FIG. 4 is a schematic diagram of an implementation solution of a method for controlling a two-phase cold plate liquid cooling system according to an embodiment of this application. As shown in FIG. 4, the basic implementation solution of the method for controlling a two-phase cold plate liquid cooling system may include: a condenser 401, a spray circulating pump 402, a gas extractor 403, a main circulating pump 404, the heat exchanger 405, first evaporators 406, second evaporators 407, a control module 408, and a data acquisition module 409.

Contents included in the condenser 401, the spray circulating pump 402, the gas extractor 403, the main circulating pump 404, the heat exchanger 405, the first evaporators 406, and the second evaporators 407, as well as generated effects, are the same as related contents described in FIG. 3, which will not be repeated herein.

The control module 408 is configured to control relevant operations in an operation process of the two-phase cold plate liquid cooling system, so as to achieve the smooth progression of each apparatus and the completion of the entire system process.

The data acquisition module 409 is configured to collect relevant data required in the operation process of the two-phase cold plate liquid cooling system, such as pressure data of a pressure sensor, and temperature data at optional times, which is not limited herein.

In this embodiment, part of gas phase is extracted to reduce a gaseous volume. When a setting value for an evaporator outlet pressure is a certain value, when the pressure value deviates from the setting value, an extraction rate is adjusted by adjusting a control valve of a corresponding evaporator to achieve a constant outlet pressure. Combined adjustment may also be adopted through the control valve, the spray circulating pump, and the gas extractor, thereby solving the technical problem of poor stability of the two-phase cold plate liquid cooling system, and achieving the technical effect of improving stability of the two-phase cold plate liquid cooling system.

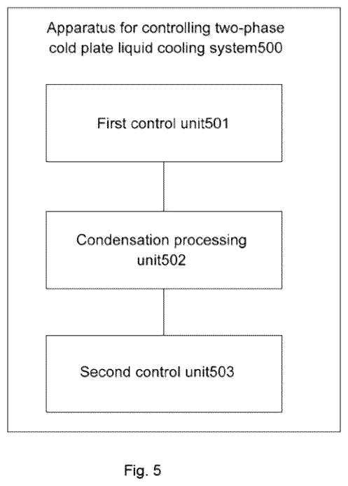

According to an embodiment of this application, an apparatus for controlling a two-phase cold plate liquid cooling system is further provided. As shown in FIG. 5, the apparatus 500 for controlling a two-phase cold plate liquid cooling system may include: a first control unit 501, a condensation processing unit 502, and a second control unit 503.

The first control unit 501 is configured to control a gas extraction tube to extract a gaseous medium from an outlet of an evaporator in an operation process of the two-phase cold plate liquid cooling system, where the two-phase cold plate liquid cooling system at least includes the gas extraction tube and the evaporator.

The condensation processing unit 502 is configured to condense the gaseous medium in a condenser of the two-phase cold plate liquid cooling system to obtain a first liquid-phase medium corresponding to the gaseous medium.

The second control unit 503 is configured to control the nozzle of the two-phase cold plate liquid cooling system to spray the first liquid-phase medium into the outlet of the evaporator, where the first liquid-phase medium is used to absorb gaseous latent heat of the gaseous medium at the outlet of the evaporator.

Optionally, the control apparatus may further include: an input unit, configured to convey the gaseous medium into the heat exchanger of the two-phase cold plate liquid cooling system before condensing the gaseous medium, where the heat exchanger is configured to heat the gaseous medium.

Optionally, the control apparatus may further include: a third control unit, configured to control a spray circulating pump of the two-phase cold plate liquid cooling system to drive the first liquid-phase medium to be sprayed into the outlet of the evaporator.

Optionally, the third control unit may include: a control module, configured to control the nozzle of the two-phase cold plate liquid cooling system to spray the first liquid-phase medium into the outlet of the evaporator, and control the spray circulating pump to drive the nozzle at the outlet of the evaporator to spray the first liquid-phase medium into the outlet of the evaporator.

Optionally, the apparatus may also include a second input unit, configured to convey the first liquid-phase medium into the heat exchanger to obtain a second liquid-phase medium, where the second liquid-phase medium is in a saturated liquid state, and the heat exchanger is configured to heat the first liquid-phase medium.

Optionally, the apparatus may also include: a conversion unit for converting the second liquid-phase medium from the saturated liquid state to the gas-liquid two-phase flow state to obtain a gas-liquid two-phase flow medium.

Optionally, the apparatus may also include: a third input unit, configured to convey the gas-liquid two-phase flow medium into the condenser in a cold state, where the gas-liquid two-phase flow medium is used for condensation treatment by the condenser.

Optionally, the conversion unit may include: a first input module, configured to convey the second liquid-phase medium into a first evaporator to obtain an original gas-liquid two-phase flow medium, where the first evaporator is configured to absorb heat from the second liquid-phase medium.

Optionally, the conversion unit may also include: a second input module for conveying the original gas-liquid two-phase flow medium into a second evaporator from the first evaporator to obtain the gas-liquid two-phase flow medium, where the second evaporator is configured to absorb heat from the original gas-liquid two-phase flow medium, and a dryness fraction of the gas-liquid two-phase flow medium is greater than that of the original gas-liquid two-phase flow medium.

Optionally, the second input unit may include: a third input module for conveying the first liquid-phase medium into the heat exchanger, and drive, based on the main circulating pump, the first liquid-phase medium to be conveyed into the heat exchanger.

Optionally, the apparatus may also use the first liquid-phase medium as subcooled liquid coolant.

In the apparatus for controlling a two-phase cold plate liquid cooling system in this embodiment, the first control unit is configured to control the gas extraction tube to extract the gaseous medium from the outlet of the evaporator in the operation process of the two-phase cold plate liquid cooling system, where the two-phase cold plate liquid cooling system at least includes the gas extraction tube and the evaporator; the condensation processing unit is configured to condense the gaseous medium in the condenser of the two-phase cold plate liquid cooling system to obtain the first liquid-phase medium corresponding to the gaseous medium; and the second control unit is configured to control the nozzle of the two-phase cold plate liquid cooling system to spray the first liquid-phase medium into the outlet of the evaporator, where the first liquid-phase medium is used to absorb the gaseous latent heat of the gaseous medium at the outlet of the evaporator. Through the above constructed apparatus for controlling the two-phase cold plate liquid cooling system, the technical problem of poor stability of the two-phase cold plate liquid cooling system is solved, and the technical effect of improving stability of the two-phase cold plate liquid cooling system is achieved.

According to an embodiment of this application, a non-volatile readable storage medium is further provided, and includes a stored program. The program performs the method for controlling a two-phase cold plate liquid cooling system in Embodiment 1.

According to an embodiment of this application, a processor is further provided. The processor is configured to run a program. The program, when running, performs the method for controlling a two-phase cold plate liquid cooling system in Embodiment 1.

The sequence numbers of the foregoing embodiments of this application are merely for the description purpose but do not represent the superiority or inferiority of the embodiments.

In the foregoing embodiments of this application, the embodiments are described with respective focuses. For a part that is not detailed in a certain embodiment, reference may be made to related descriptions in other embodiments.

In the several embodiments provided in this application, it should be understood that the disclosed technical content may be implemented in other manners. The apparatus embodiments described above are merely illustrative, such as the unit division which may be a logical function division, and during practical implementation, there may be additional division manners. For example, a plurality of units or components may be combined or integrated into another system, or some features may be ignored or not executed. In addition, shown or discussed mutual coupling or direct coupling, or communication connection may be an indirect coupling or communication connection through some interfaces, units, or modules, in an electrical form or other forms.

The units described as separate components may or may not be physically separated, and components displayed as units may or may not be physical units, that is, may be located in one position, or may be distributed over a plurality of units. Some or all of the units may be selected according to actual needs to achieve the objectives of the solutions of the embodiments.

In addition, functional units in the embodiments of this application may be integrated into a processing unit, or the units may exist physically separately, or two or more units may be integrated into a unit. The above integrated unit may be implemented in the form of hardware or a software functional unit.

When the integrated unit is implemented in the form of the software functional unit and sold or used as an independent product, the integrated unit may be stored in a computer-readable storage medium. Based on such understanding, the technical solutions of this application essentially or parts making contribution to the related art, or all or some of the technical solutions may be embodied in the form of a software product. The computer software product is stored in a storage medium and includes a plurality of instructions used to allow a computer device (which may be a personal computer, a server, a network device, or the like) to perform all or some of the steps of the methods in the embodiments of this application. The aforementioned storage medium includes: a U disk, a Read Only Memory (ROM), a Random Access Memory (RAM), a mobile hard drive, a magnetic disk, an optical disk, or other media capable of storing program code.

The above contents are merely optional implementations of this application. It should be noted that a plurality of improvements and modifications may also be made by those of ordinary skill in the art without departing from the principle of this application, and shall be considered within the scope of protection of this application.

1. A method for controlling a two-phase cold plate liquid cooling system, comprising:
controlling a gas extraction tube to extract a gaseous medium from an outlet of an evaporator in an operation process of the two-phase cold plate liquid cooling system, wherein the two-phase cold plate liquid cooling system at least comprises the gas extraction tube and the evaporator;
condensing the gaseous medium in a condenser of the two-phase cold plate liquid cooling system to obtain a first liquid-phase medium corresponding to the gaseous medium; and
controlling a nozzle of the two-phase cold plate liquid cooling system to spray the first liquid-phase medium into the outlet of the evaporator, wherein the first liquid-phase medium is used to absorb gaseous latent heat of the gaseous medium at the outlet of the evaporator.

2. The method according to claim 1, wherein before condensing the gaseous medium, the method further comprises:
conveying the gaseous medium into a heat exchanger of the two-phase cold plate liquid cooling system, wherein the heat exchanger is configured to heat the gaseous medium.

3. The method according to claim 1, further comprising:
controlling a spray circulating pump of the two-phase cold plate liquid cooling system to drive the first liquid-phase medium to be sprayed into the outlet of the evaporator.

4. The method according to claim 3, wherein the controlling the nozzle of the two-phase cold plate liquid cooling system to spray the first liquid-phase medium into the outlet of the evaporator comprises:
controlling the spray circulating pump to drive the nozzle at the outlet of the evaporator to spray the first liquid-phase medium into the outlet of the evaporator.

5. The method according to claim 1, further comprising:
conveying the first liquid-phase medium into a heat exchanger to obtain a second liquid-phase medium, wherein the second liquid-phase medium is in a saturated liquid state, and the heat exchanger is configured to heat the first liquid-phase medium;
converting the second liquid-phase medium from the saturated liquid state to a gas-liquid two-phase flow state to obtain a gas-liquid two-phase flow medium; and
conveying the gas-liquid two-phase flow medium into the condenser in a cold state, wherein the gas-liquid two-phase flow medium is used for condensation treatment by the condenser.

6. The method according to claim 5, wherein the converting the second liquid-phase medium from the saturated liquid state to the gas-liquid two-phase flow state to obtain the gas-liquid two-phase flow medium comprises:
conveying the second liquid-phase medium into a first evaporator to obtain an original gas-liquid two-phase flow medium, wherein the first evaporator is configured to absorb heat from the second liquid-phase medium; and
conveying the original gas-liquid two-phase flow medium into a second evaporator from the first evaporator to obtain the gas-liquid two-phase flow medium, wherein the second evaporator is configured to absorb heat from the original gas-liquid two-phase flow medium, and a dryness fraction of the gas-liquid two-phase flow medium is greater than that of the original gas-liquid two-phase flow medium.

7. The method according to claim 5, wherein the conveying the first liquid-phase medium into the heat exchanger comprises:
driving, based on a main circulating pump, the first liquid-phase medium to be conveyed into the heat exchanger.

8. The method according to claim 1, wherein the first liquid-phase medium is subcooled liquid coolant.

9. A two-phase cold plate liquid cooling system, comprising:
a gas extraction tube, configured to extract a gaseous medium from an outlet of an evaporator;
a condenser, configured to condense the gaseous medium to obtain a first liquid-phase medium corresponding to the gaseous medium; and
a nozzle, configured to spray the first liquid-phase medium into the outlet of the evaporator.

10. The system according to claim 9, wherein the two-phase cold plate liquid cooling system further comprises a heat exchanger, wherein the heat exchanger is configured to heat the gaseous medium before condensing the gaseous medium.

11. The system according to claim 10, wherein the heat exchanger is further configured to heat the first liquid-phase medium to obtain a second liquid-phase medium, wherein the second liquid-phase medium is in a saturated liquid state.

12. The system according to claim 11, wherein the two-phase cold plate liquid cooling system further comprises a first evaporator and a second evaporator, wherein the first evaporator is configured to absorb heat from the second liquid-phase medium to obtain an original gas-liquid two-phase flow medium, the second evaporator is configured to absorb heat from the original gas-liquid two-phase flow medium, and a dryness fraction of the gas-liquid two-phase flow medium is greater than that of the original gas-liquid two-phase flow medium.

13. The system according to claim 12, wherein the condenser is further configured to condense the gas-liquid two-phase flow medium.

14. The system according to claim 9, wherein the two-phase cold plate liquid cooling system further comprises a main circulating pump, wherein the main circulating pump is configured to drive the first liquid-phase medium to be conveyed into a heat exchanger, wherein the heat exchanger is configured to heat the gaseous medium before condensing the gaseous medium.

15. The system according to claim 9, wherein the nozzle and the gas extraction tube are located at the outlet of the evaporator.

16. (canceled)

17. (canceled)

18. (canceled)

19. A non-volatile readable storage medium, wherein the non-volatile readable storage medium stores a computer program, the computer program, when being executed on a processor, causes the processor to execute operations comprising:
controlling a gas extraction tube to extract a gaseous medium from an outlet of an evaporator in an operation process of the two-phase cold plate liquid cooling system, wherein the two-phase cold plate liquid cooling system at least comprises the gas extraction tube and the evaporator;
condensing the gaseous medium in a condenser of the two-phase cold plate liquid cooling system to obtain a first liquid-phase medium corresponding to the gaseous medium; and
controlling a nozzle of the two-phase cold plate liquid cooling system to spray the first liquid-phase medium into the outlet of the evaporator, wherein the first liquid-phase medium is used to absorb gaseous latent heat of the gaseous medium at the outlet of the evaporator.

20. (canceled)

21. The method according to claim 3, wherein the spray circulating pump is configured to provide the liquid phase power.

22. The method according to claim 4, wherein the nozzle and the gas extraction tube are located at the outlet of the evaporator.

23. The system according to claim 9, wherein the two-phase cold plate liquid cooling system comprises a spray circulating pump, wherein the spray circulating pump is configured to drive the first liquid-phase medium to be sprayed into the outlet of the evaporator.

24. The system according to claim 9, wherein the first liquid-phase medium is subcooled liquid coolant.
